(19) United States
(12) Patent Application Publication
(10) Pub. No.: US 2021/0348262 A1
(43) Pub. Date: Nov. 11, 2021

(54) CONTACT COATING OF ELECTRICAL CONNECTOR AND PREPARATION METHOD THEREOF

(71) Applicants: NO. 59 INSTITUTE OF CHINA ORDNANCE INDUSTRY, Chongqing (CN); UNIVERSITY OF SCIENCE AND TECHNOLOGY LIAONING, Anshan (CN)

(72) Inventors: Hulin WU, Chongqing (CN); Lunwu ZHANG, Chongqing (CN); Zhiwen XIE, Anshan (CN); Qiang CHEN, Chongqing (CN); Xu GAO, Anshan (CN); Yongjun CHEN, Anshan (CN); Lin XIANG, Chongqing (CN); Haiqing NING, Chongqing (CN); Yong ZHONG, Chongqing (CN); Suying HU, Anshan (CN); Shuai WU, Chongqing (CN); Bo FENG, Anshan (CN); Hong SU, Chongqing (CN); Xiaohui WANG, Chongqing (CN); Bo HUANG, Chongqing (CN); Di WU, Anshan (CN)

(21) Appl. No.: 17/134,257

(22) Filed: Mar. 10, 2021

(30) Foreign Application Priority Data
May 6, 2020 (CN) 202010371884.7

(51) Int. Cl. C23C 14/35; H01R 43/16

(52) U.S. Cl. CPC C23C 14/35; H01R 43/16

(57) ABSTRACT

The present invent belongs to the technical field of plating by sputtering coating forming materials, and particularly relates to a contact coating of an electrical connector. In the coating, chromium nitride is doped with precious metal elements.

### CROSS-REFERENCE TO RELATED APPLICATIONS

This application claims the benefit of priority from Chinese Patent Application No. 202010371884.7, filed on May 6, 2020. The content of the aforementioned application, including any intervening amendments thereto, is incorporated herein by reference in its entirety.

### TECHNICAL FIELD

The present invent belongs to the technical field of plating by sputtering coating forming materials, and particularly relates to a contact coating of an electrical connector and a preparation method thereof.

### BACKGROUND OF THE PRESENT INVENTION

An electrical connector is a basic component for realizing transmission and control of electrical signals and power connection between electronic and electrical devices, and is widely used in aerospace, electronics, communication and other industries (“Research on Parametric Modeling and Simulation Test of Electrical Connector”, Tianhui Luan, Master's Thesis, Northeastern University, 2012, lines 1-3 of paragraph 1 of the abstract, published on Dec. 31, 2012).

The electrical connector is mainly used for electric energy transmission and signal control of a control system, and its quality and reliability are crucial for the normal running of various devices and systems. According to statistics, at present, 70% of failures (faults) of electronic and electrical equipment are caused by the failure of electronic elements (“Study on Failure Mode and Reliability Guarantee of Electrical Connectors”, Xiao Chang, reliability and environment test of electronic products, No. 3, 2019, lines 1-2 of abstract on page 47, published on Dec. 31, 2019; and “Study on Coupling Failure Mechanism and Reliability of Electrical Connectors”, Bo Huang, Ph.D. Thesis, University of Electronic Science and Technology of China, 2016, Lines 1-6 of paragraph 1 of the abstract, published on Aug. 1, 2017).

Contacts are conductive parts and core components of the electrical connectors, which transmit energy or signals from wires and cables connected to tail ends of the electrical connectors to the corresponding contacts of electrical connectors matched therewith, and usually require sockets to correspond to pins one by one (“Joint Innovation Research on Contact Materials of High Reliability Electrical Connectors”, Fenwei Yang, Electromechanical Elements, Vol. 34, No. 1, 2014, Lines 1-4 of last paragraph on Page 40, published on Feb. 28, 2014).

However, the existing contacts of the electrical connectors cannot well play a corresponding role.

### SUMMARY OF THE PRESENT INVENTION

In view of this, a purpose of the present invention is to provide a coating capable of making a contact of an electrical connector better play the corresponding role.

In order to realize the above purpose, the present invention adopts the following technical solution:

A contact protective coating of an electrical connector is provided, wherein chromium nitride is doped with precious metal elements.

The electrical connector is a basic component for realizing transmission and control of electrical signals and power connection between electronic and electrical devices.

The contact refers to a conductive part in an element that is matched with a corresponding conductive par to provide an electrical path.

Further, the precious metal element is a unitary element of Pt, Au or Ir, a binary element of PtAu, PtIr or AuIr or a ternary element of PtAuIr.

Further, a thickness of the coating is 800 nm-1000 nm.

Further, a doping amount of the precious metal element is 3 mol %-10 mol %, which is based on a ratio in a molar weight of chromium nitride.

A second purpose of the present invention is to provide a method for preparing a protective coating, which includes the following steps:

A, sputtering and cleaning a matrix to be deposited and a target material in a vacuum or inert gas atmosphere; and

B, depositing a chromium target doped with precious metal on the surface of the matrix to be deposited processed in the step A to form a coating in the inert gas or vacuum atmosphere.

Further, in the step A, the working atmosphere is argon, a flow rate is 100-150 sccm, and a vacuum degree in sputtering is 0.2-0.6 GPa; the matrix is preheated to 200-400° C.; a deposition bias voltage is −70 to −120 V; the sputtering and cleaning time of the matrix is 30-120 min; and the sputtering and cleaning time of the target material is 1-5 min.

Further, in the step B, the working atmosphere is mixed gas of argon and nitrogen, a flow rate is 100-150 sccm, and a vacuum degree in sputtering is 0.2-0.6 GPa; the matrix is preheated to 200-400° C.; a deposition bias voltage is −80 to −130V; the deposition time is 30-120 min; and the power of chromium target is 3-8 kW.

Further, in the step B, in the process of depositing the coating on the surface of the matrix, the matrix rotates at a constant speed along with a turntable in a magnetron sputtering system.

Further, the magnetron sputtering system includes a vacuum chamber, a target material arranged on the periphery of the vacuum chamber and a rotatable turntable arranged in the vacuum chamber.

Further, the matrix to be deposited is a metal material.

Further, the purity of the chromium target is greater than or equal to 99.9%.

A further purpose of the present invention is to protect the application of the coating in the contact of the electrical connector.

The present invention has the beneficial effects:

The coating of the present invention has excellent electrical conductivity and corrosion resistance and can better enable the contact of the electrical connector to play the corresponding role.

The coating of the present invention has excellent wear resistance.

The coating of the present invention has good toughness.

The preparation method of the coating of the present invention is simple, high in efficiency, low in cost, conducive to industrialized production, and widely applicable to the coating of the contact of the electrical connector in a corrosive environment.

### BRIEF DESCRIPTION OF THE DRAWINGS

FIG. 1 shows a high-purity Cr target (purity ≥99.9%) mixed and embedded with precious metal and used in a coating of embodiment 1;

FIG. 2 shows surface and sectional morphology test of the coating prepared in the embodiment 1, wherein 2a is a surface morphology image, and 2b is a sectional morphology image;

FIG. 3 is a graph illustrating a hardness test result of the coating prepared in the embodiment 1 (i.e. a nanoindentation loading unloading curve);

FIG. 4 is an image illustrating a surface element analysis result of the coating prepared in the embodiment 1 (i.e. a coating surface element distribution image);

FIG. 5 is a graph illustrating a phase structure test result of the coating prepared in the embodiment 1;

FIG. 6 shows corrosion resistance test results of the coating prepared in the embodiment 1 and a matrix processed in a comparative example 1;

FIG. 7 is a graph illustrating electric resistivity test results of the coatings prepared in the embodiment 1 and a comparative example 2; and

FIG. 8 is a graph illustrating a wear resistance test result of the coating prepared in the embodiment 1.

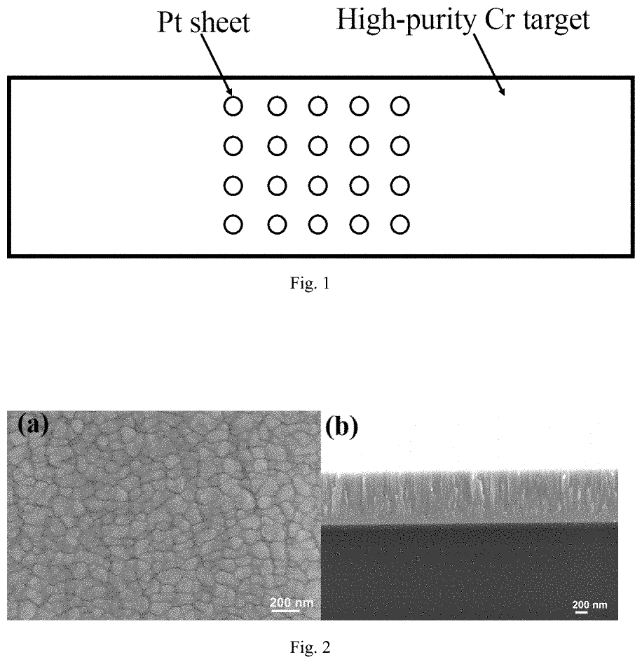

### DETAILED DESCRIPTION OF THE PRESENT INVENTION

Embodiments are provided to better explain the content of the present invention, and the content of the present invention is not limited to the provided embodiments. Non-essential improvements and adjustments made by those killed in the art for implementation solutions according to the content of the present invention still fall within the protection scope of the present invention.

### Embodiment 1

A contact coating of an electrical connector takes 316 stainless steel as a matrix, and uses a plasma enhanced magnetron sputtering coating process to deposit a CrN—Pt coating. Specific preparation steps are as follows:

S1: The matrix to be deposited is mechanically polished; after the matrix surface is polished to a mirror face, the matrix is subjected to ultrasonic oscillation cleaning successively by deionized water, acetone (analytically pure) and alcohol (analytically pure) respectively for 20 minutes, and the cleaned matrix is dried for 20 minutes in a drying box at 80° C.

S2: The matrix to be deposited processed in the step S1 is placed onto a turntable disposed in a vacuum chamber. A vacuum pump is started to vacuumize the vacuum chamber, so that a vacuum degree in the vacuum chamber reaches 5×10⁻³ Pa. In this process, the vacuum chamber is heated, and the heating temperature is 300° C.

S3: Argon is introduced into the vacuum room at a flow rate of 100 sccm, and in the argon atmosphere, the matrix to be deposited and the target material are sputtered and cleaned. During the sputtering, the deposition bias voltage is −120 V, and the sputtering and cleaning time of the matrix is 60 minutes; and when the target material is cleaned, the target power is set as 500 W, and the target material is shielded by a shielding cover. The cleaning time of the target material is 5 minutes.

S4: A Pt metal block is embedded in the high-purity Cr target (purity is 99.9%) to form a Cr—Pt hybrid target, and the target is used to sputter and deposit a CrN—Pt coating on the surface of the matrix to be deposited; and mixed gas of nitrogen and argon is introduced into the vacuum chamber, wherein the flow rate of the nitrogen and argon is 100 sccm; during the sputtering, the vacuum degree is 0.5 GPa; the preheating temperature of the matrix to be deposited is 300° C.; the deposition bias voltage is −100V; and the power of the Cr—Pt hybrid target is 5 kW.

S5: In the process of sputtering and depositing the coating, the matrix rotates at a constant speed along with a turntable in a magnetron sputtering system. The magnetron sputtering system includes the vacuum chamber, the rotatable turntable arranged in the vacuum chamber and a target material arranged on the periphery of the turntable.

S6: After the vacuum chamber is cooled to the room temperature, a sample is taken out of the vacuum chamber.

### Comparative Example 1

A 316L stainless steel matrix is mechanically polished; after the matrix surface is polished to a mirror face, the matrix is subjected to ultrasonic oscillation cleaning successively by deionized water, acetone (analytically pure) and alcohol (analytically pure) respectively for 20 minutes, and the cleaned matrix is dried for 20 minutes in a drying box at 80° C.

### Comparative Example 2

A contact coating of an electrical connector takes 316 stainless steel as a matrix, and uses a plasma enhanced magnetron sputtering coating process to deposit a CrN coating. Specific preparation steps are as follows:

S1: The matrix to be deposited is mechanically polished, after the matrix surface is polished to a mirror face, the matrix is subjected to ultrasonic oscillation cleaning successively by deionized water, acetone (analytically pure) and alcohol (analytically pure) respectively for 20 minutes, and the cleaned matrix is dried for 20 minutes in a drying box in an atmosphere of 80° C.

S2: The matrix to be deposited processed in the step S1 is placed onto a turntable disposed in a vacuum chamber. A vacuum pump is started to vacuumize the vacuum chamber, so that a vacuum degree in the vacuum chamber reaches 5×10⁻³ Pa. In this process, the vacuum chamber is heated, and the heating temperature is 300° C.

S3: Argon is introduced into the vacuum room at a flow rate of 100 sccm, and in the argon atmosphere, the matrix to be deposited and the target material are sputtered and cleaned. During the sputtering, the deposition bias voltage is −120 V, and the sputtering and cleaning time of the matrix is 60 minutes; and when the target material is cleaned, the target power is set as 500 W, and the target material is shielded by a shielding cover. The cleaning time of the target material is 5 minutes.

S4: A high-purity Cr target (purity is 99%) is used to sputter and deposit a CrN coating on the surface of the matrix to be deposited; and mixed gas of nitrogen and argon is introduced into the vacuum chamber, wherein the flow rate of the nitrogen and argon is 100 sccm; during the sputtering, the vacuum degree is 0.5 GPa; the preheating temperature of the matrix to be deposited is 300° C.; the deposition bias voltage is −100V; and the power of the high-purity Cr target is 5 kW.

S5: In the process of sputtering and depositing the coating, the matrix rotates at a constant speed along with a turntable in a magnetron sputtering system. The magnetron sputtering system includes a vacuum chamber, the rotatable turntable arranged in the vacuum chamber and a target material arranged on the periphery of the turntable.

S6: After the vacuum chamber is cooled to the room temperature, a sample is taken out of the vacuum chamber.

Performance Test

A field emission scanning electronic microscope (FESEM) was used to observe surface and sectional morphologies of a coating prepared in embodiment 1. Results are shown in FIG. 2, wherein 2a is a surface morphology image, and 2b is a sectional morphology image.

It can be seen from FIG. 2 that the surface of the coating prepared in the embodiment 1 is composed of crystal particles in different sizes, which has no obvious holes, cracks and other defects, and is uniform and smooth in structure; and the section of the coating is of a cylindrical crystal particle micro-structure. The cylindrical crystal particles are fine and smooth and are well bonded with the matrix without obvious stripping or cracking.

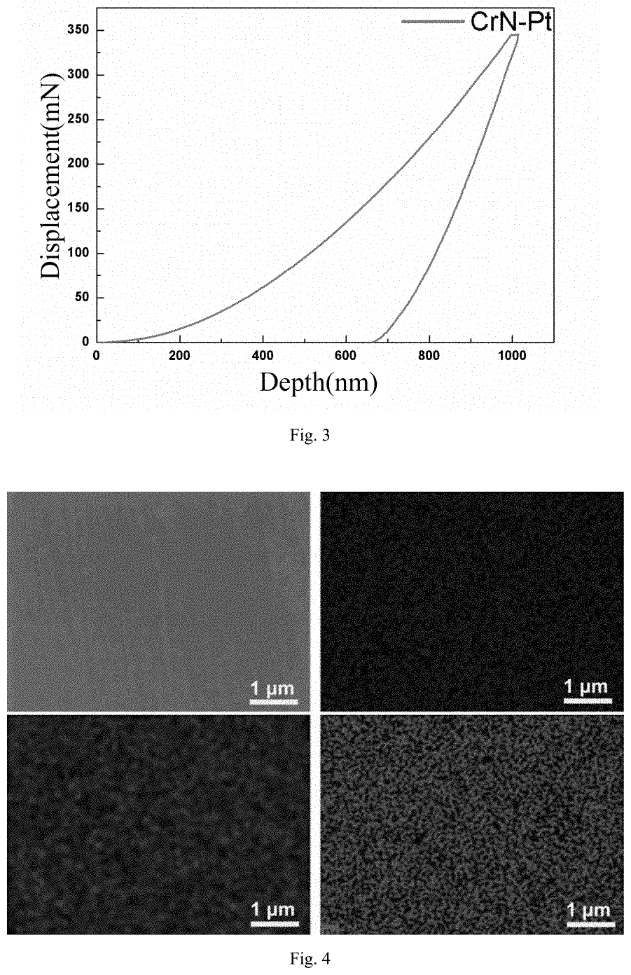

A nanoindentor with a Berkovich diamond pressure head was used to test hardness of the coating prepared in the embodiment 1. A test mode was a continuous stiffness method (CSM). In order to guarantee the accuracy and reliability of data, 20 different areas were selected on a sample. After numerical values with large deviation were removed, the average hardness value was used as final hardness. Meanwhile, in order to prevent the impact of the matrix on a measurement result, a hardness value of the coating in a depth about 100 nm was taken as a calculation standard. Results are shown in FIG. 3.

It can be seen from FIG. 3 through an Oliver-Pharr method (“An improved technique for determining hardness and elastic modulus using load and displacement sensing indentation experiments”, Oliver W. C., Pharr G. M., Journal of Materials Research, 1992, 7(06), 1564-1583) that the hardness of the CrN—Pt coating prepared in the embodiment 1 is 19.77 GPa, and elastic modulus was 254.6 GPa. Researches show that the H/E value may be used as an evaluation standard for judging the toughness of the coating. The greater the H/E value is, the better the toughness of the coating is (“Microstructure and mechanical properties of TiZrAlN nanocomposite thin films by CFUBMS”, Y. J. Kim, H. Y. Lee, T. J. Byun, J. G. Han, Thin Solid Films, 2008, 516(11), 3651-3655). By calculation, it can be seen that the H/E value of embodiment 1 is 0.078. This proves that the coating of the present invention has good toughness.

An X-ray energy spectrometer (EDS) of the field emission scanning electronic microscope (FESEM) was used to analyze elements of the coating prepared in the embodiment 1. Results are shown in FIG. 4.

It can be seen from FIG. 4 that the elements on the surface of the coating prepared in the embodiment 1 are distributed uniformly without agglomeration phenomenon.

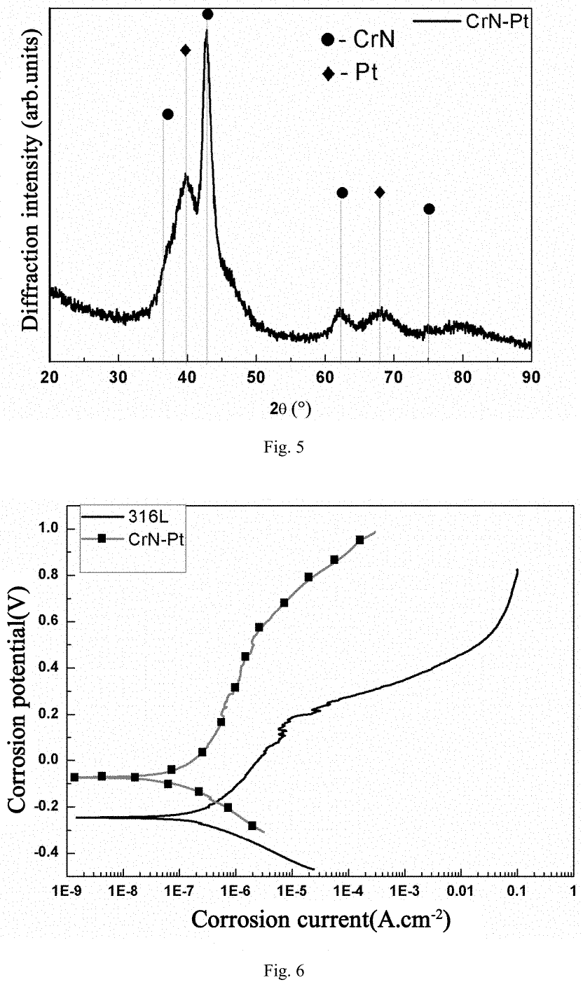

The XRD was used to test a phase structure of the coating prepared in the embodiment 1. To avoid the interference of the matrix, a small-angle measurement mode was used to analyze a crystal structure of the coating. A grazing incidence was 1°, a scanning range was 20°-90°. Results are shown in FIG. 5.

It can be seen from FIG. 5 that the coating prepared in the embodiment 1 is composed of a CrN phase and element Pt. This proves that the element Pt exits in the coating of the present invention in a form of free state.

A CS350 electrochemical workstation was used to test corrosion resistance of the coating prepared in the embodiment 1 and a 316L stainless steel matrix processed in a comparative example 1, specifically as follows: a three-electrode system was used, a sample to be tested was a working electrode (WE), a saturated calomel electrode (SCE) was a reference electrode (RE), and a Pt electrode was an auxiliary electrode (CE). Electrolyte was 3.5% NaCL solution. Results are shown in FIG. 6.

It can be seen from FIG. 6 that compared with the comparative example 1, a corrosion potential and a corrosion current density of the coating prepared in the embodiment 1 are improved to different extents. The corrosion current density is increased from 2.816×10⁻⁷ A/cm² to 1.001×10⁻⁷ A/cm². The corrosion potential is increased from −245 mV to −73 mV. This proves that the coating of the present invention has excellent corrosion resistance.

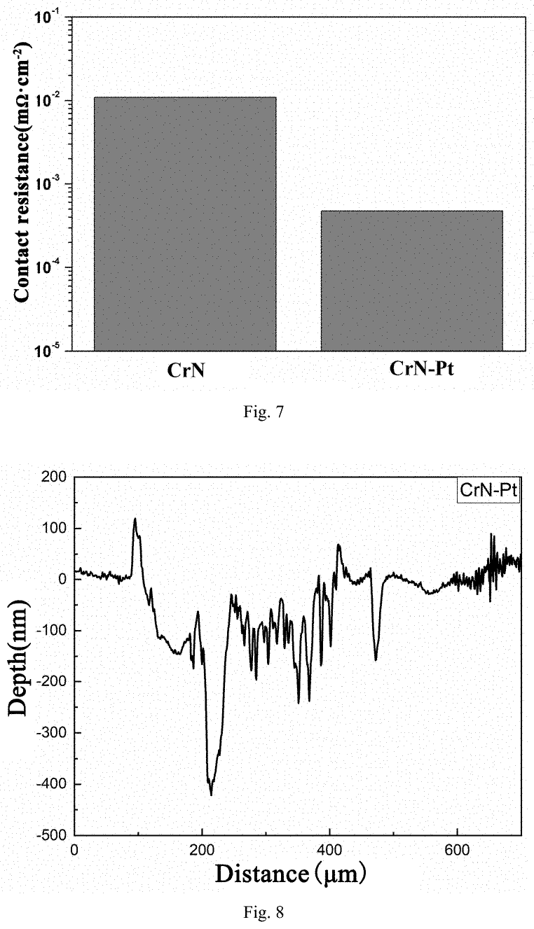

Electrical resistivity of the coatings prepared in embodiment 1 and the comparative example 2 were tested by a Hall effect tester (a membrane thickness is set as 1035 μm). Results are shown in FIG. 7.

It can be seen from FIG. 7 that compared with the comparative example 2, the electrical resistivity of the coating prepared in the embodiment 1 is obviously reduced. This proves that the coating of the present invention has excellent electrical conductivity.

A ball-disc friction wear testing machine was used to test wear performance of the coating prepared in the embodiment 1. Parameters were set as follows: a rotation speed was 300 Rad; a load was 2 N; a grinding ball was a Si3 N4 ceramic ball with a diameter of 6 mm; a test radius was 6 mm; and test time was 30 minutes. A step profiler was used to test a wear area on the surface of a tested sample to obtain a grinding crack contour. Results are shown in FIG. 8. A volume abrasion rate was calculated by adopting an Archard formula. The calculation formula is as follows:

$$k = \frac{V}{W \cdot l} \qquad ( 1 )$$

In the formula, V is an abrasion volume in mm³; k is a volume abrasion rate in mm³(N·m)⁻¹; I is a reciprocating sliding distance in m; and W is the load in N.

It can be seen from FIG. 8 that a maximum abrasion depth of the coating prepared in the embodiment 1 is 422.7 nm; and by calculation, the volume abrasion rate of the coating prepared in the embodiment 1 is about 2.07×10⁻⁶ mm³/(N·m). This proves that the coating of the present invention has excellent wear resistance.

Furthermore, it should be understood that although this specification is described according to the embodiments, each embodiment does not include only one independent technical solution. The description of the specification is only for the sake of clarity. Those skilled in the art shall take the specification as a whole, and the technical solutions in each embodiment can be combined appropriately to form other embodiments that can be understood by those skilled in the art.

We claim:

1. A contact protective coating of an electrical connector, wherein chromium nitride is doped with precious metal elements.

2. The coating according to claim 1, wherein the precious metal element is a unitary element of Pt, Au or Ir, a binary element of PtAu, PtIr or AuIr or a ternary element of PtAuIr.

3. The coating according to claim 1, wherein thickness of the coating is 800 nm-1000 nm.

4. The coating according to claim 1, wherein a doping amount of the precious metal element is 3 mol %-10 mol %, which is based on a ratio in a molar weight of chromium nitride.

5. A method for preparing the coating of claim 1, comprising the following steps:
A, sputtering and cleaning a matrix to be deposited and a target material in a vacuum or inert gas atmosphere; and
B, depositing a chromium target doped with precious metal on the surface of the matrix to be deposited processed in the step A to form a coating in the inert gas or vacuum atmosphere.

6. The method for preparing the coating according to claim 5, wherein in the step A, the working atmosphere is argon, a flow rate is 100-150 sccm, and a vacuum degree in sputtering is 0.2-0.6 GPa; the matrix is preheated to 200-400° C.; a deposition bias voltage is −70 to −120 V; the sputtering and cleaning time of the matrix is 30-120 min; and the sputtering and cleaning time of the target material is 1-5 min.

7. The method for preparing the coating according to claim 5, wherein in the step B, the working atmosphere is mixed gas of argon and nitrogen, a flow rate is 100-150 sccm, and a vacuum degree in sputtering is 0.2-0.6 GPa; the matrix is preheated to 200-400° C.; a deposition bias voltage is −80 to −130V; the deposition time is 30-120 min; and the power of chromium target is 3-8 kW.

8. The method for preparing the coating according to claim 6, wherein in the step B, the working atmosphere is mixed gas of argon and nitrogen, a flow rate is 100-150 sccm, and a vacuum degree in sputtering is 0.2-0.6 GPa; the matrix is preheated to 200-400° C.; a deposition bias voltage is −80 to −130V; the deposition time is 30-120 min; and the power of chromium target is 3-8 kW.

9. The method for preparing the coating according to claim 5, wherein in the step B, in the process of depositing the coating on the surface of the matrix, the matrix rotates at a constant speed along with a turntable in a magnetron sputtering system.

10. The method for preparing the coating according to claim 6, wherein in the step B, in the process of depositing the coating on the surface of the matrix, the matrix rotates at a constant speed along with a turntable in a magnetron sputtering system.

11. The method for preparing the coating according to claim 7, wherein in the step B, in the process of depositing the coating on the surface of the matrix, the matrix rotates at a constant speed along with a turntable in a magnetron sputtering system.

12. The method for preparing the coating according to claim 8, wherein in the step B, in the process of depositing the coating on the surface of the matrix, the matrix rotates at a constant speed along with a turntable in a magnetron sputtering system.

13. An application of the coating of claim 1 in the contact of the electrical connector.

14. An application of the coating of claim 2 in the contact of the electrical connector.

15. An application of the coating of claim 3 in the contact of the electrical connector.

16. An application of the coating of claim 4 in the contact of the electrical connector.

17. A method for preparing the coating of claim 2, comprising the following steps:
A, sputtering and cleaning a matrix to be deposited and a target material in a vacuum or inert gas atmosphere; and
B, depositing a chromium target doped with precious metal on the surface of the matrix to be deposited processed in the step A to form a coating in the inert gas or vacuum atmosphere.

18. A method for preparing the coating of claim 3, comprising the following steps:
A, sputtering and cleaning a matrix to be deposited and a target material in a vacuum or inert gas atmosphere; and
B, depositing a chromium target doped with precious metal on the surface of the matrix to be deposited processed in the step A to form a coating in the inert gas or vacuum atmosphere.

19. A method for preparing the coating of claim 4, comprising the following steps:
A, sputtering and cleaning a matrix to be deposited and a target material in a vacuum or inert gas atmosphere; and
B, depositing a chromium target doped with precious metal on the surface of the matrix to be deposited processed in the step A to form a coating in the inert gas or vacuum atmosphere.

20. The method for preparing the coating according to claim 19, wherein in the step A, the working atmosphere is argon, a flow rate is 100-150 sccm, and a vacuum degree in sputtering is 0.2-0.6 GPa; the matrix is preheated to 200-400° C.; a deposition bias voltage is −70 to −120 V; the sputtering and cleaning time of the matrix is 30-120 min; and the sputtering and cleaning time of the target material is 1-5 min.
